(19) United States
(12) Patent Application Publication
(10) Pub. No.: US 2025/0015765 A1
(43) Pub. Date: Jan. 9, 2025

(54) IMPEDANCE DETECTION CIRCUIT, IMPEDANCE CONTROL CIRCUIT, AND DOHERTY AMPLIFIER CIRCUIT

(71) Applicant: Murata Manufacturing Co., Ltd., Kyoto (JP)

(72) Inventor: Shohei IMAI, Kyoto (JP)

(21) Appl. No.: 18/888,758

(22) Filed: Sep. 18, 2024

Related U.S. Application Data
(63) Continuation of application No. PCT/JP2023/013286, filed on Mar. 30, 2023.

(30) Foreign Application Priority Data
Mar. 31, 2022 (JP) 2022-059840

(51) Int. Cl. H03F 1/02; G01R 25/00; G01R 27/16; H03F 3/24; H03G 3/30

(52) U.S. Cl. CPC H03F 1/0288; G01R 25/005; G01R 27/16; H03F 3/245; H03G 3/3042; H03F 2200/451; H03G 2201/103; H03G 2201/307

(57) ABSTRACT

An impedance detection circuit includes: a first detector that detects a first voltage amplitude at an end of an inverter circuit having the end to which a radio frequency signal is input and having a different end from which a signal is output; a second detector that detects a second voltage amplitude of the different end of the inverter circuit; and a phase difference detector that detects a phase difference between a phase of a voltage across the end of the inverter circuit and a phase of a voltage across the different end of the inverter circuit. An absolute value of a product of diagonal elements of a dependent parameter for the inverter circuit is smaller than an absolute value of a product of off-diagonal elements.

### CROSS REFERENCE TO RELATED APPLICATION

This is a continuation of International Application No. PCT/JP2023/013286 filed on Mar. 30, 2023 which claims priority from Japanese Patent Application No. 2022-059840 filed on Mar. 31, 2022. The contents of these applications are incorporated herein by reference in their entireties.

### BACKGROUND ART

### Technical Field

The present disclosure relates to an impedance detection circuit, an impedance control circuit, and a Doherty amplifier circuit.

Patent Document 1 describes an amplification device that adjusts the phase or the amplitude of a second signal input to a second amplification part, by using the reflection coefficient of each of an output from the first amplification part and an output from the second amplification part.
Patent Document 1: Japanese Unexamined Patent Application Publication No. 2017-169146

### BRIEF SUMMARY

However, the amplification device described in Patent Document 1 detects the reflection coefficient of each of the output from the first amplification part and the output from the second amplification part and thus requires two directional couplers. Directional couplers are large due to the structure thereof and are not usable for, for example, mobile communication terminals.

The present disclosure prevents a circuit from being upsized and also to detect impedance.

An impedance detection circuit according to an aspect of the present disclosure includes: a first detector that detects a first voltage amplitude at an end of an inverter circuit having the end to which a radio frequency signal is input and having a different end from which a signal is output; a second detector that detects a second voltage amplitude of the different end of the inverter circuit; and a phase difference detector that detects a phase difference between a phase of a voltage across the end of the inverter circuit and a phase of a voltage across the different end of the inverter circuit. An absolute value of a product of diagonal elements of a dependent parameter for the inverter circuit is smaller than an absolute value of a product of off-diagonal elements.

An impedance control circuit according to an aspect of the present disclosure includes: the impedance detection circuit of the present disclosure; and at least one of a first transistor and a second transistor, the first transistor having a base or a gate to which a first signal based on the first voltage amplitude and the second voltage amplitude is input and having a collector from which first current is output to the end of the inverter circuit, a second transistor having a base or a gate to which a second signal based on the first voltage amplitude and the second voltage amplitude is input and having a collector from which second current is output to the different end of the inverter circuit.

A Doherty amplifier circuit according to an aspect of the present disclosure includes: a carrier amplifier that amplifies an input radio frequency signal; a peaking amplifier that amplifies an input radio frequency signal; and the impedance control circuit of the present disclosure. The inverter circuit serves as a Doherty combiner that combines a signal output by the carrier amplifier and a signal output by the peaking amplifier.

According to the present disclosure, the circuit may be prevented from being upsized and may also detect impedance.

### BRIEF DESCRIPTION OF THE DRAWINGS

FIG. 1 is a diagram illustrating the configuration of an amplifier circuit of a first embodiment.

FIG. 2 is a chart illustrating the circuit simulation results of the amplifier circuit of the first embodiment.

FIG. 3 is a graph illustrating the circuit simulation results of the amplifier circuit of the first embodiment.

FIG. 4 is a diagram illustrating the configuration of an amplifier circuit in a first example of a second embodiment.

FIG. 5 is a diagram illustrating the configuration of an amplifier circuit in a second example of the second embodiment.

FIG. 6 is a diagram illustrating the configuration of an amplifier circuit in a third example of the second embodiment.

FIG. 7 is a chart illustrating the circuit simulation results of an amplifier circuit in a third example of the second embodiment.

FIG. 8 is a graph illustrating the circuit simulation results of the amplifier circuit in the third example of the second embodiment.

FIG. 9 is a diagram illustrating the configuration of an inverter circuit in a first example of a third embodiment.

FIG. 10 is a diagram illustrating the configuration of an inverter circuit in a second example of the third embodiment.

FIG. 11 is a diagram illustrating the configuration of an inverter circuit in a third example of the third embodiment.

FIG. 12 is a diagram illustrating the configuration of an inverter circuit in a fourth example of the third embodiment.

FIG. 13 is a diagram illustrating the configuration of an inverter circuit in a fifth example of the third embodiment.

FIG. 14 is a diagram illustrating the configuration of an amplifier circuit of a fourth embodiment.

FIG. 15 is a chart illustrating the circuit simulation results of the amplifier circuit of the fourth embodiment.

FIG. 16 is a graph illustrating the circuit simulation results of the amplifier circuit of the fourth embodiment.

FIG. 17 is a diagram illustrating the configuration of an amplifier circuit of a fifth embodiment.

FIG. 18 is a diagram illustrating the configuration of an amplifier circuit of a sixth embodiment.

FIG. 19 is a diagram illustrating the configuration of an amplifier circuit of a seventh embodiment.

FIG. 20 is a diagram illustrating the configuration of an equivalent circuit of the amplifier circuit of the seventh embodiment.

FIG. 21 is a diagram illustrating the configuration of an amplifier circuit of an eighth embodiment.

FIG. 22 is a diagram illustrating the configuration of an amplifier circuit of a modification of the eighth embodiment.

### DETAILED DESCRIPTION

Hereinafter, embodiments of an impedance detection circuit, an impedance control circuit, and a Doherty amplifier circuit of the present disclosure will be described in detail based on the drawings. The embodiments do not limit the present disclosure. It goes without necessarily saying that each embodiment is exemplification and configurations illustrated in different embodiments can be partially replaced or combined. After a second embodiment, the description of a matter common to that in a first embodiment is omitted, and one or more different points will only be described. In particular, the same advantageous effects and operations of the same configuration are not referred to in each embodiment.

### First Embodiment

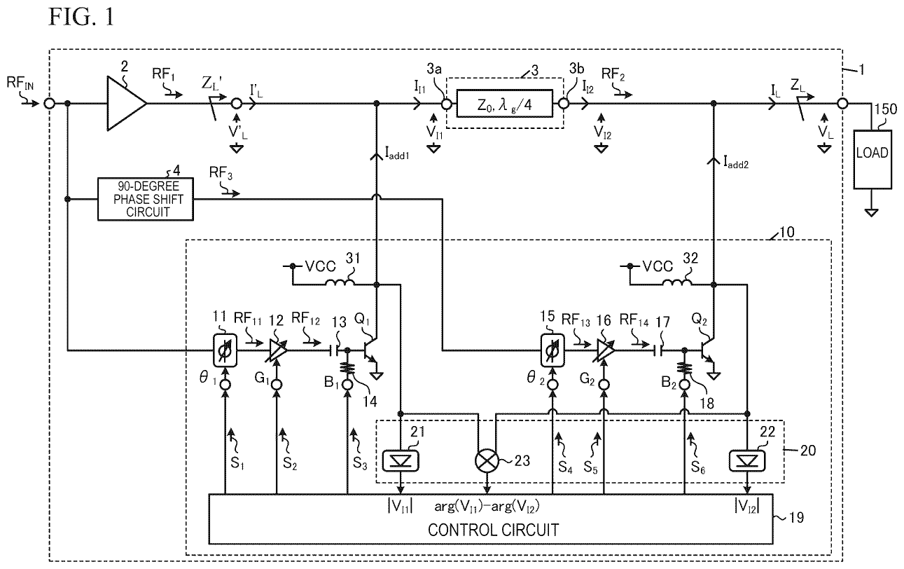

FIG. 1 is a diagram illustrating the configuration of an amplifier circuit of a first embodiment.

An amplifier circuit 1 includes an amplifier 2, an inverter circuit 3, a 90-degree shift circuit 4, and an impedance control circuit 10.

The amplifier 2 amplifies a radio frequency signal RF_{IN} and outputs a radio frequency signal RF₁ to an end 3a of the inverter circuit 3. The inverter circuit 3 receives the radio frequency signal RF₁ at the end 3a and outputs a radio frequency signal RF₂ from a different end 3b to a load 150.

The amplifier 2 assumes that impedance Z_{L}′ seen from the output terminal thereof to the load 150 has a value assumed in designing. A general emitter-grounded or source-grounded single-ended amplifier, a differential amplifier, a Doherty amplifier, an envelope tracking amplifier, and the like are exemplified as the amplifier 2; however, the present disclosure is not limited to these.

An output voltage of the amplifier 2 is a voltage V_{L}′, and output current is current I_{L}′.

The inverter circuit 3 converts the value of the impedance Z_{L} for the load 150 to a reciprocal thereof (admittance). The inverter circuit 3 is a ¼ wavelength line of characteristic impedance Z₀; however, the present disclosure is not limited to this.

A voltage input to the end 3a of the inverter circuit 3 is a voltage V_{I1}, and input current thereof is current I_{I1}. A voltage output from the different end 3b of the inverter circuit 3 is a voltage V_{I2}, and output current is current I_{I2}.

A voltage input to the load 150 is a voltage V_{L}, and current input to the load 150 is current I_{L}.

The impedance control circuit 10 controls the impedance Z_{L}′. The impedance Z_{L}′ is also the input impedance of the inverter circuit 3.

### (Configuration of Impedance Control Circuit)

The impedance control circuit 10 includes transistors Q₁ and Q₂, variable phase control circuits 11 and 15, variable gain control circuits 12 and 16, capacitors 13 and 17, resistors 14 and 18, a control circuit 19, and an impedance detection circuit 20.

Each transistor is a bipolar transistor in the present disclosure; however, the present disclosure is not limited to this. A heterojunction bipolar transistor (HBT) is exemplified as the bipolar transistor; however, the present disclosure is not limited to this. The transistor may be, for example, a field effect transistor (FET). The transistor may be a multi-finger transistor in which a plurality of unit transistors are electrically connected in parallel. A unit transistor denotes a minimum configuration of a transistor.

If the transistor is a FET, the drain of the FET corresponds to the collector of the bipolar transistor, the gate thereof corresponds to the base, and the source thereof corresponds to the emitter.

The transistor Q₁ corresponds to an example of “first transistor” of the present disclosure. The transistor Q₂ corresponds to an example of “second transistor” of the present disclosure. The variable gain control circuit 12 corresponds to an example of “first variable gain control circuit” of the present disclosure. The variable gain control circuit 16 corresponds to an example of “second variable gain control circuit” of the present disclosure. The variable phase control circuit 11 corresponds to an example of “first variable phase control circuit” of the present disclosure. The variable phase control circuit 15 corresponds to an example of “second variable phase control circuit” of the present disclosure.

The impedance detection circuit 20 includes detectors 21 and 22 and a phase difference detector 23.

The detector 21 corresponds to an example of “first detector” of the present disclosure. The detector 22 corresponds to an example of “second detector” of the present disclosure.

The detector 21 detects the voltage V_{I1} across the end 3a of the inverter circuit 3 and outputs a voltage amplitude |V_{I1}| to the control circuit 19.

The voltage amplitude |V_{I1}| corresponds to an example of “first voltage amplitude” of the present disclosure.

The detector 22 detects the voltage V_{I2} across the different end 3b of the inverter circuit 3 and outputs a voltage amplitude |V_{I2}| to the control circuit 19.

The voltage amplitude |V_{I2}| corresponds to an example of “second voltage amplitude” of the present disclosure.

The phase difference detector 23 detects a phase difference (arg(V_{I1})−arg(V_{I2})) between the voltage V_{I1} and the voltage V_{I2} and outputs the phase difference (arg(V_{I1})−arg(V_{I2})) to the control circuit 19.

Based on the voltage amplitudes |V_{I1}| and |V_{I2}| and the phase difference (arg(V_{I1})−arg(V_{I2})), the control circuit 19 outputs a phase control signal S₁ to the variable phase control circuit 11, outputs a gain control signal S₂ to the variable gain control circuit 12, and outputs a bias control signal S₃ to an end of the resistor 14. Alternatively, based on the voltage amplitudes |V_{I1}| and |V_{I2}| and the phase difference (arg(V_{I1})−arg(V_{I2})), the control circuit 19 outputs a phase control signal S₄ to the variable phase control circuit 15, outputs a gain control signal S₅ to the variable gain control circuit 16, and outputs a bias control signal S₆ to an end of the resistor 18.

The variable phase control circuit 11 changes the phase of the radio frequency signal RF_{IN} by a phase θ₁ based on the phase control signal S₁ and outputs a radio frequency signal RF₁₁ to the variable gain control circuit 12.

The variable gain control circuit 12 changes the amplitude of the radio frequency signal RF₁₁ by using a gain G₁ based on the gain control signal S₂ and outputs a radio frequency signal RF₁₂ via the capacitor 13 that is a DC blocking capacitor to the base of the transistor Q₁.

A different end of the resistor 14 is electrically connected to the base of the transistor Q₁. A bias voltage B₁ is input from the different end of the resistor 14 to the base of the transistor Q₁.

The emitter of the transistor Q₁ is electrically connected to the reference potential. A voltage for substrate and source is exemplified as the reference potential; however, the present disclosure is not limited to this. The collector of the transistor Q₁ is electrically connected to a power supply voltage VCC with a choke coil 31 interposed therebetween, and power is supplied.

The transistor Q₁ outputs current I_{add1} according to the radio frequency signal RF₁₂ and the bias voltage B₁ from the collector to the end 3a of the inverter circuit 3. In other words, the transistor Q₁ outputs a radio frequency signal from the collector to the end 3a of the inverter circuit 3, the radio frequency signal being obtained by amplifying the radio frequency signal RF₁₂.

The current I_{add1} corresponds to an example of “first current” of the present disclosure.

If a reactance component (imaginary component) of the impedance Z_{L}′ is not required to be compensated, the variable phase control circuit 11 does not have to be provided. That is, the variable gain control circuit 12 may change the amplitude of the radio frequency signal RF_{IN} by using the gain G₁ based on the gain control signal S₂ and may output the radio frequency signal RF₁₂ to the base of the transistor Q₁ via the capacitor 13 that is the DC blocking capacitor.

Both or only one of the variable gain control circuit 12 and the resistor 14 may be provided. That is, both or only one of the radio frequency signal RF₁₂ and the bias voltage B₁ may be input to the base of the transistor Q₁.

One or both of the radio frequency signal RF₁₂ and the bias voltage B₁ correspond to an example of “first signal” of the present disclosure. Specifically, the radio frequency signal RF₁₂ is a signal the phase or the gain of which is controlled in accordance with the phase control signal S₁ based on the voltage amplitudes |V_{I1}| and |V_{I2}| and the gain control signal S₂ and is “first signal” based on the voltage amplitudes |V_{I1}| and |V_{I2}|. The bias voltage B₁ is a signal controlled in accordance with the bias control signal S₃ based on the voltage amplitudes |V_{I1}| and |V_{I2}| as described above and is “first signal” based on the voltage amplitudes |V_{I1}| and |V_{I2}|.

The 90-degree shift circuit 4 shifts the phase of the radio frequency signal RF_{IN} by 90 degrees and outputs a radio frequency signal RF₃ to the variable phase control circuit 15.

The variable phase control circuit 15 changes the phase of the radio frequency signal RF₃ by a phase θ₂ based on the phase control signal S₄ and outputs a radio frequency signal RF₁₃ to the variable gain control circuit 16.

If the control circuit 19 is designed to add 90-degree offset to the phase control signal S₄, the 90-degree shift circuit 4 does not have to be provided.

The variable gain control circuit 16 changes the amplitude of the radio frequency signal RF₁₃ by using a gain G₂ based on the gain control signal S₅ and outputs a radio frequency signal RF₁₄ to the base of the transistor Q₂ via the capacitor 17 that is the DC blocking capacitor.

A different end of the resistor 18 is electrically connected to the base of the transistor Q₂. A bias voltage B₂ is input from the different end of the resistor 18 to the base of the transistor Q₂.

The emitter of the transistor Q₂ is electrically connected to the reference potential. The collector of the transistor Q₂ is electrically connected to the power supply voltage VCC with a choke coil 32 interposed therebetween, and power is supplied.

The transistor Q₂ outputs current I_{add2} according to the radio frequency signal RF₁₄ and the bias voltage B₂ from the collector to the different end 3b of the inverter circuit 3.

The current I_{add2} corresponds to an example of “second current” of the present disclosure.

If the reactance component (imaginary component) of the impedance Z_{L}′ is not required to be compensated, the variable phase control circuit 15 does not have to be provided. That is, the variable gain control circuit 16 may change the amplitude of the radio frequency signal RF₃ by using the gain G₂ based on the gain control signal S₅ and output the radio frequency signal RF₁₄ to the base of the transistor Q₂ via the capacitor 17 that is the DC blocking capacitor.

Both or only one of the variable gain control circuit 16 and the resistor 18 may be provided. That is, both or only one of the radio frequency signal RF₁₄ and the bias voltage B₂ may be input to the base of the transistor Q₂.

One or both of the radio frequency signal RF₁₄ and the bias voltage B₂ correspond to an example of “second signal” of the present disclosure.

### (Goal for Control of Impedance Control Circuit)

If the impedance Z_{L}′ deviates from the value assumed in designing in the amplifier 2, characteristics are deteriorated on occasions. For example, substantial deviation of the impedance Z_{L}′ from the value assumed in designing in the amplifier 2 causes substantial distortion in the radio frequency signals RF₁ and RF₂ and thus misoperation in communication apparatus nearby in some cases. In particular, the amplifier 2 that is a Doherty amplifier is typically less resistant to change in the impedance Z_{L}′.

Hence, the impedance control circuit 10 performs control to cause the impedance Z_{L}′ to have a value close to the value assumed in designing. This enables the impedance control circuit 10 to prevent the distortion in the radio frequency signals RF₁ and RF₂.

### (Impedance Control Circuit Operations)

(1)

The inverter circuit 3 has a relationship that the voltage V_{I2} is proportional to the current I_{I1} in a carrier frequency. That is, Formula (1) below holds true.

V_{I2}=−j*Z_{INV}*I_{I1} (1)

In Formula (1), Z_{INV} is referred to as inverter impedance and is a positive or negative real number. The inverter impedance corresponds to mirror impedance of two-terminal pair network.

The inverter circuit 3 also has a relationship that the current I_{I2} is proportional to the voltage V_{I1} in the carrier frequency. That is, Formula (2) below holds true.

$${I}_{I 2} = - j * 1 / {Z}_{INV} * {V}_{I 1} \qquad ( 2 )$$

The control circuit 19 detects the voltage amplitudes |V_{I1}| and |V_{I2}| of the respective voltages V_{I1} and V_{I2} and the phase difference (arg(V_{I1})−arg(V_{I2})) between the voltage V_{I1} and the voltage V_{I2} by using Formula (1) and Formula (2) and may thereby calculate the impedance Z_{INV}. Specifically, by using the detectors 21 and 22, the control circuit 19 detects the voltage amplitudes |V_{I1}| and |V_{I2}| of the respective voltages V_{I1} and V_{I2} derived according to Formula (1) and Formula (2). By using the phase difference detector 23, the control circuit 19 also detects the phase difference (arg(V_{I1})−arg(V_{I2})) between the voltage V_{I1} and the voltage V_{I2} derived according to Formula (1) and Formula (2). The control circuit 19 calculates the impedance Z_{INV} by using the detected voltage amplitudes |V_{I1}| and |V_{I2}| and the phase difference (arg(V_{I1})−arg(V_{I2})).

Further, the impedance control circuit 10 outputs the high frequency current I_{add1} or I_{add2} to an end portion of the inverter circuit 3 and may thereby control the impedance Z_{L}′ seen from the amplifier 2.

Specifically, if the impedance Z_{L}′ is low, the impedance control circuit 10 outputs the current I_{add1} to the end 3a of the inverter circuit 3. The current I_{add1} flows to the inverter circuit 3. Accordingly, the current I_{L}′ is decreased by an amount corresponding to the current I_{add1}. That is, the impedance control circuit 10 may decrease the current I_{L}′ output by the amplifier 2. This enables the impedance control circuit 10 to increase the impedance Z_{L}′ seen from the amplifier 2 to the load 150 and prevent the impedance Z_{L}′ from varying.

If the impedance Z_{L}′ is high, the impedance control circuit 10 outputs the current I_{add2} to the different end 3b of the inverter circuit 3. The current I_{add2} flows to the load 150. Accordingly, the current I_{I2} is decreased by an amount corresponding to the current I_{add2}. That is, the impedance control circuit 10 may decrease the current I_{I2} output by the inverter circuit 3. The decreased current I_{I2} causes the voltage V_{L}′ output by the amplifier 2 to be low due to the characteristics of the inverter circuit 3. The impedance control circuit 10 may thereby decrease the impedance Z_{L}′ seen from the amplifier 2 to the load 150 and prevent the impedance Z_{L}′ from varying.

Further, if the impedance control circuit 10 includes the variable phase control circuits 11 and 15, the following actions are provided. That is, if the impedance control circuit 10 controls the phase of the current I_{add1} and I_{add2} based on the phase difference (arg(V_{I1})−arg(V_{I2})), the control of the impedance Z_{L}′ described above may also be act on the reactance component (imaginary component). This enables the impedance control circuit 10 to further prevent the impedance Z_{L}′ from varying.

(2)

In FIG. 1, for example, the inverter circuit 3 has the characteristic impedance Z₀ and is a line with a ¼ wavelength in a carrier frequency (resonant frequency). However, the inverter circuit 3 is not limited to this, and it suffices that Formula (1) and Formula (2) described above hold true in the carrier frequency.

As a known circuit for which Formula (1) and (2) hold true, a circuit composed of lumped elements, a circuit obtained by combining a transmission line and lumped elements, a circuit using a transducer are exemplified. These circuits will be described for other embodiments.

According to Formula (1) and (2), the inverter circuit 3 is a circuit for which Formula (3) below holds true near the carrier frequency.

$$\begin{matrix}[ Math 1 ] & \\ ( \begin{matrix}{V}_{I 1} \\ {I}_{I 1}\end{matrix} ) = ( \begin{matrix}0 & {jZ}_{INV} \\ \frac{j}{{Z}_{INV}} & 0\end{matrix} ) ( \begin{matrix}{V}_{I 2} \\ {I}_{I 2}\end{matrix} ) & ( 3 )\end{matrix}$$

For example, the amplifier 2 is designed on the assumption of the impedance Z_{L}′ of 50Ω (ohm) and the characteristic impedance Z₀ of 50Ω; however, the present disclosure is not limited to these. If the characteristic impedance Z₀ is different from the assumed impedance (50Ω) of the impedance Z_{L}′, the following processing may be performed in such a manner that the voltage amplitude |V_{I1}| or |V_{I2}| is multiplied by the constant.

(3)

First, control performed for lower impedance Z_{L}′ by the impedance control circuit 10 will be described. If the impedance Z_{L}′ is lower than the assumed impedance (for example, 50Ω), the voltage amplitude |V_{I1}| lower than the voltage amplitude |V_{I2}| is observed.

In this case, the impedance control circuit 10 outputs the high frequency current I_{add1} to the end 3a of the inverter circuit 3 and thereby decreases the current I_{L}′. This enables the impedance control circuit 10 to increase the impedance Z_{L}′.

For example, the control circuit 19 controls the gain G₁ of the variable gain control circuit 12 by using Formula (4) below. In Formula (4), α₁ is sensitivity (a coefficient or a constant) for controlling the gain G₁ and is determined in consideration of the gain of the transistor Q₁.

$$\begin{matrix}[ Math 2 ] & \\ {G}_{1} ( dB ) = \{ \begin{matrix}{α}_{1} 10 log ( \vert {V}_{I 2} \vert - \vert {V}_{I 1} \vert ) & ( where \vert {V}_{I 2} \vert > \vert {V}_{I 1} \vert ) \\ - ∞ & ( where \vert {V}_{I 2} \vert \leq \vert {V}_{I 1} \vert )\end{matrix} & ( 4 )\end{matrix}$$

As represented by Formula (4), with the increase of a difference between the voltage amplitude |V_{I2}| and the voltage amplitude |V_{I1}|, the impedance control circuit 10 increases the amplitude of the radio frequency signal RF₁₂ to be input to the base of the transistor Q₁ and thereby increases the high frequency current I_{add1} to be output from the collector of the transistor Q₁.

Formula (4) is the simplest expression for the impedance control circuit 10 to achieve the control goal, and the present disclosure is not limited to this. The impedance control circuit 10 may use a ratio between the voltage amplitude |V_{I2}| and the voltage amplitude |V_{I1}| instead of the difference between the voltage amplitude |V_{I2}| and the voltage amplitude |V_{I1}|. The impedance control circuit 10 may also use combination of these or a high-order function such as a quadric.

If the impedance Z_{L}′ seen from the amplifier 2 is about to be low because the output impedance of the amplifier circuit 1 deviates from the assumed value, the impedance control circuit 10 may automatically increase the impedance Z_{L}′ by performing the control represented by Formula (4). The amplifier 2 thereby exists from the low impedance state.

Further, if a reactance component (imaginary component) is generated in the inverter circuit 3, the phase difference (arg(V_{I1})−arg(V_{I2})) is shifted from 90 degrees. The control circuit 19 controls the phase θ₁ based on a shift amount of the phase difference (arg(V_{I1})−arg(V_{I2})) from 90 degrees. This enables the impedance control circuit 10 to control the phase of the radio frequency signal RF₁₂ to be input to the base of the transistor Q₁. The impedance control circuit 10 may thus compensate the reactance component of the impedance Z_{L}′.

For example, the control circuit 19 controls the phase θ₁ by using Formula (5) below. In Formula (5), B₁ is sensitivity (a coefficient or a constant) for controlling the phase.

$${θ}_{1} ( deg ) = - {β}_{1} ( arg ( {V}_{I 1} ) - arg ( {V}_{I 2} ) - 90 ) ... ( 5 ) \qquad ( 4 )$$

Control performed for higher impedance Z_{L}′ by the impedance control circuit 10 will then be described. If the impedance Z_{L}′ is higher than the assumed impedance (for example, 5002), the voltage amplitude |V_{I1}| higher than the voltage amplitude |V_{I2}| is observed.

In this case, the impedance control circuit 10 outputs the high frequency current I_{add2} to the different end 3b of the inverter circuit 3 and thereby decreases the current I₁₂. The decreased current I₁₂ causes the voltage V_{I1} to be low due to the characteristics of the inverter circuit 3. As the result, the impedance control circuit 10 may decrease the voltage Vi′ and thus decrease the impedance Z_{L}′.

For example, the control circuit 19 controls the gain G₂ of the variable gain control circuit 16 by using Formula (6) below. In Formula (6), α₂ is sensitivity (a coefficient or a constant) for controlling the gain G₂ and is determined in consideration of the gain of the transistor Q₂.

$$\begin{matrix}[ Math 3 ] & \\ {G}_{2} ( dB ) = \{ \begin{matrix}{α}_{2} 10 log ( \vert {V}_{I 1} \vert - \vert {V}_{I 2} \vert ) & ( where \vert {V}_{I 1} \vert > \vert {V}_{I 2} \vert ) \\ - ∞ & ( where \vert {V}_{I 1} \vert \leq \vert {V}_{I 2} \vert )\end{matrix} & ( 6 )\end{matrix}$$

As represented by Formula (6), with the increase of a difference between the voltage amplitude |V_{I1}| and the voltage amplitude |V_{I2}|, the impedance control circuit 10 increases the amplitude of the radio frequency signal RF₁₄ to be input to the base of the transistor Q₂ and thereby increases the high frequency current I_{add2} to be output from the collector of the transistor Q₂.

Formula (6) is the simplest expression for the impedance control circuit 10 to achieve the control goal, and the present disclosure is not limited to this. The impedance control circuit 10 may use a ratio between the voltage amplitude |V_{I1}| and the voltage amplitude |V_{I2}|, instead of the difference between the voltage amplitude |V_{I1}| and the voltage amplitude |V_{I2}|. The impedance control circuit 10 may also use combination of these or a high-order function such as a quadric.

If the impedance Z_{L}′ seen from the amplifier 2 is about to be high because the output impedance of the amplifier circuit 1 deviates from the assumed value, the impedance control circuit 10 may automatically decrease the impedance Z_{L}′ by performing the control represented by Formula (6). The amplifier 2 thereby exists from the high impedance state.

Further, if a reactance component (imaginary component) is generated in the inverter circuit 3, the phase difference (arg(V_{I1})−arg(V_{I2})) is shifted from 90 degrees. The control circuit 19 controls the phase θ₂ based on a shift amount of the phase difference (arg(V_{I1})−arg(V_{I2})) from 90 degrees. This enables the impedance control circuit 10 to control the phase of the radio frequency signal RF₁₄ to be input to the base of the transistor Q₂. The impedance control circuit 10 may thus compensate the reactance component of the impedance Z_{L}′.

For example, the control circuit 19 controls the phase θ₂ by using Formula (7) below. In Formula (7), β₂ is sensitivity (a coefficient or a constant) for controlling the phase.

$${θ}_{2} ( deg ) = {β}_{2} ( arg ( {V}_{I 1} ) - arg ( {V}_{I 2} ) - 90 ) \qquad ( 7 )$$

### (Circuit Simulation Results of Impedance Control Circuit)

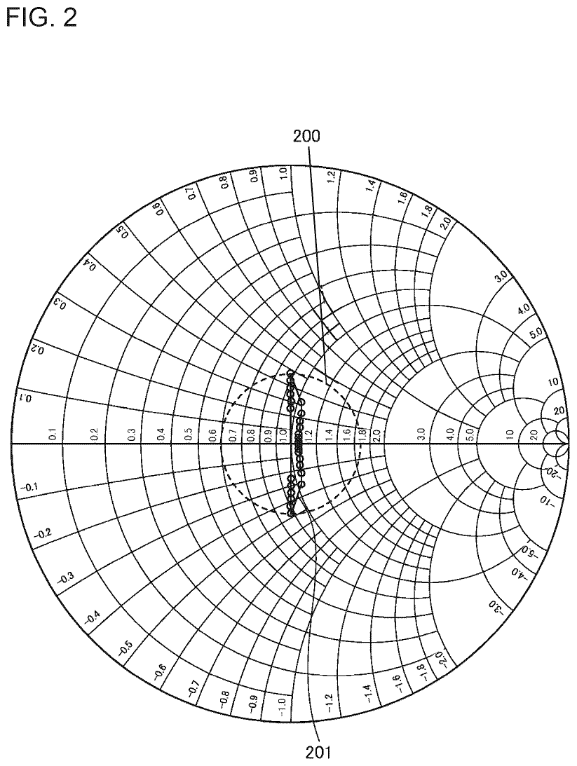

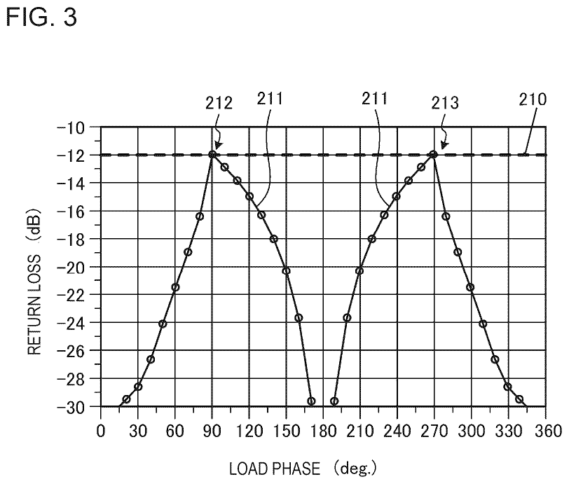

FIG. 2 and FIG. 3 are charts illustrating circuit simulation results of the amplifier circuit of the first embodiment.

In the circuit simulation in FIG. 2 and FIG. 3, the reflection coefficient of the load 150 is 0.25 (return loss (R.L.)=−12.0 dB and voltage standing wave ratio (VSWR)=1.67), and the impedance control described above is performed in such a manner that the reflection phase is changed from 0 degrees to 360 degrees.

FIG. 2 is a Smith chart of the circuit simulation results. In FIG. 2, a waveform 200 represents the impedance Z_{L} of the load 150, and a waveform 201 represents the impedance Z_{L}′ seen from the amplifier 2 to the load 150.

FIG. 3 is a graph with the horizontal axis representing load phase and the vertical axis representing return loss. In FIG. 3, a waveform 210 represents the return loss of the load 150, and a waveform 211 represents the return loss, of the inverter circuit 3, seen from the amplifier 2.

The waveform 201 is inward of the waveform 200. The waveform 211 is downward of the waveform 210. That is, it is understood that the return loss is decreased. It is thus understood that the impedance Z_{L}′ approaches the value assumed in designing.

However, a point 212 and a point 213 where the load phases are respectively 90 degrees and 270 degrees represent |V_{I1}|=|V_{I2}|, and the gain G₁ of the variable gain control circuit 12 and the gain G₂ of the variable gain control circuit 16 are each 0. That is, it is not possible for the impedance control circuit 10 to control the impedance Z_{L}′ sufficiently. However, if the load phase is 90 degrees or 270 degrees, performance is not remarkably deteriorated in the amplifier 2 on occasions, which is acceptable.

### (Summarization)

As described above, the impedance detection circuit 20 detects the voltage amplitudes |V_{I1}| and |V_{I2}| and the phase difference (arg(V_{I1})−arg(V_{I2})) and may thereby prevent the circuit from being upsized and also detect the impedance of the inverter circuit 3.

If the impedance Z_{L}′ becomes low, the impedance control circuit 10 may perform control to increase the impedance Z_{L}′ to have the value assumed in designing by outputting the current I_{add1} to the end 3a of the inverter circuit 3.

If the impedance Z_{L}′ becomes high, the impedance control circuit 10 may perform control to decrease the impedance Z_{L}′ to have the value assumed in designing by outputting the current I_{add2} to the different end 3b of the inverter circuit 3.

As described above, in the amplifier circuit 1, the impedance Z_{L}′ seen from the amplifier 2 to the load 150 is controlled to have the value assumed in designing, and thus the distortion of the radio frequency signals RF₁ and RF₂ may be prevented.

### Second Embodiment

Among components in the second embodiment, the same components as those in the first embodiment are denoted by the same reference numerals, and description thereof is omitted.

For the first embodiment, the case of controlling all of the gain G₁ of the path for compensating low impedance and the phase θ₁ as well as the gain G₂ of the path for compensating high impedance and the phase θ₂ has heretofore been described. However, if one or more of these are controlled, a partial effect may be provided.

### First Example

If only the impedance Z_{L}′ is required to be compensated, the 90-degree shift circuit 4, the transistor Q₂, the variable phase control circuit 15, the variable gain control circuit 16, the capacitor 17, and the resistor 18 may be omitted.

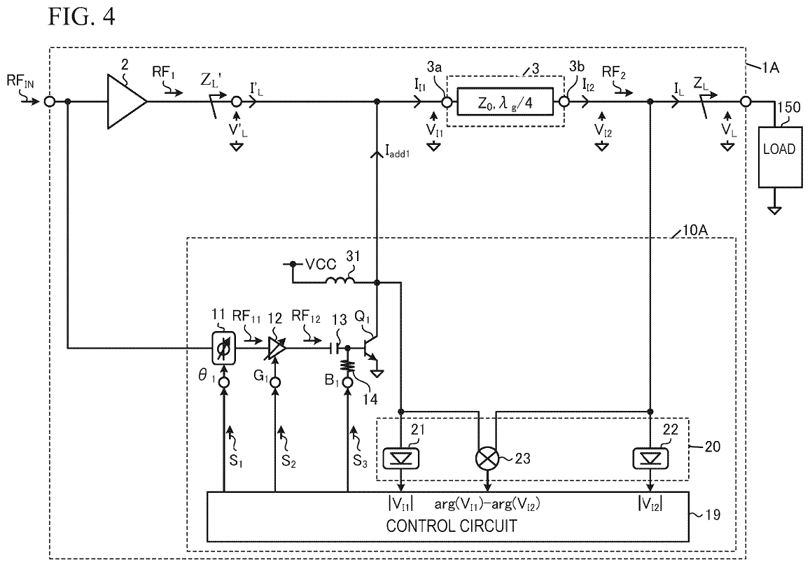

FIG. 4 is a diagram illustrating the configuration of an amplifier circuit in a first example of the second embodiment.

An amplifier circuit 1A does not include the 90-degree shift circuit 4, as compared with the amplifier circuit 1 (see FIG. 1). The amplifier circuit 1A includes an impedance control circuit 10A instead of the impedance control circuit 10, as compared with the amplifier circuit 1.

The impedance control circuit 10A does not include the transistor Q₂, the variable phase control circuit 15, the variable gain control circuit 16, the capacitor 17, and the resistor 18, as compared with the impedance control circuit 10.

If the impedance Z_{L}′ becomes low, the impedance control circuit 10A outputs the current I_{add1} to the end 3a of the inverter circuit 3. The impedance control circuit 10A may thereby increase the impedance Z_{L}′ and perform control to have the value assumed in designing.

### Second Example

If only a high impedance Z_{L}′ is required to be compensated, the transistor Q₁, the variable phase control circuit 11, the variable gain control circuit 12, the capacitor 13, and the resistor 14 may be omitted.

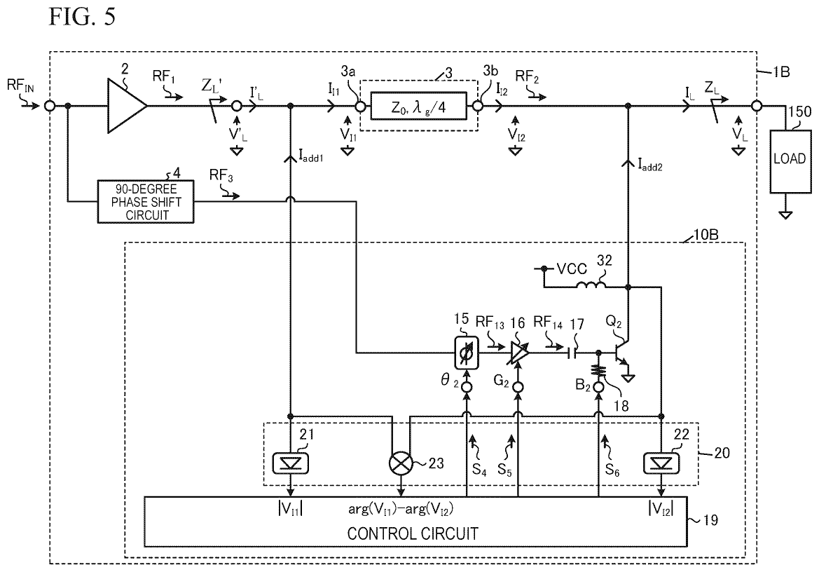

FIG. 5 is a diagram illustrating the configuration of an amplifier circuit in a second example of the second embodiment.

An amplifier circuit 1B includes an impedance control circuit 10B instead of the impedance control circuit 10, as compared with the amplifier circuit 1 (see FIG. 1).

The impedance control circuit 10B does not include the transistor Q₁, the variable phase control circuit 11, the variable gain control circuit 12, the capacitor 13, and the resistor 14, as compared with the impedance control circuit 10.

If the impedance Z_{L}′ becomes high, the impedance control circuit 10B outputs the current I_{add2} to the different end 3b of the inverter circuit 3. The impedance control circuit 10B may thereby decrease the impedance Z_{L}′ and perform control to have the value assumed in designing.

### Third Example

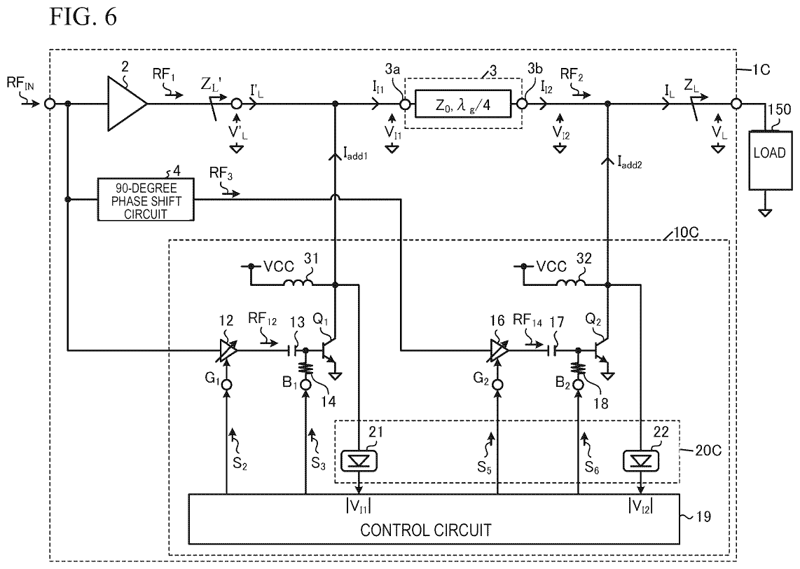

FIG. 6 is a diagram illustrating the configuration of an amplifier circuit in a third example of the second embodiment.

An amplifier circuit 1C includes an impedance control circuit 10C instead of the impedance control circuit 10, as compared with the amplifier circuit 1 (see FIG. 1). The impedance control circuit 10C does not include the variable phase control circuit 11 and the variable phase control circuit 15, as compared with the impedance control circuit 10. The impedance control circuit 10C includes an impedance detection circuit 20C instead of the impedance detection circuit 20, as compared with the impedance control circuit 10. The impedance detection circuit 20C does not include the phase difference detector 23, as compared with the impedance detection circuit 20.

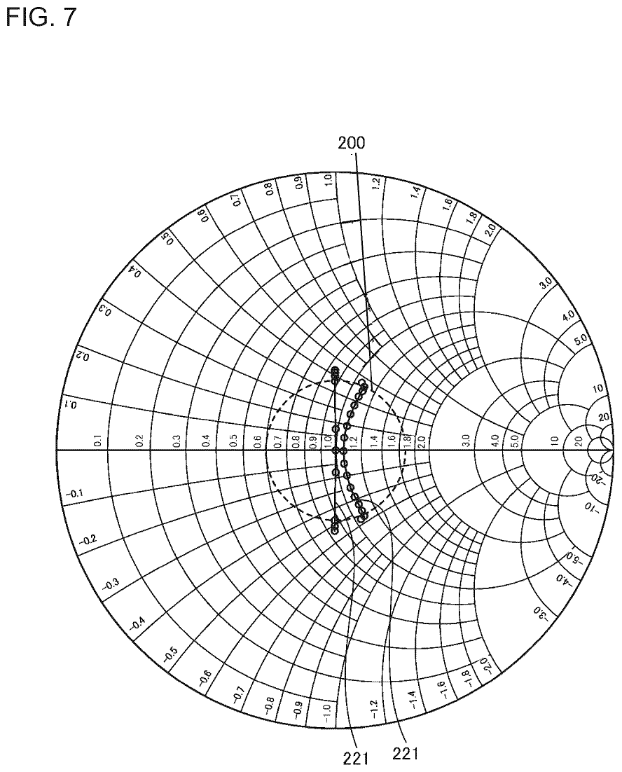

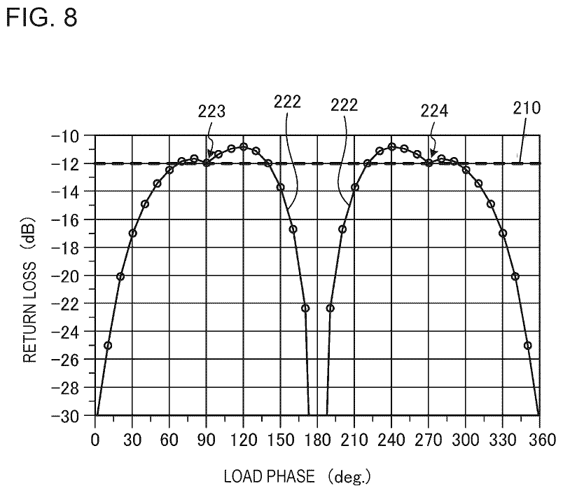

FIG. 7 and FIG. 8 are charts illustrating the circuit simulation results of the amplifier circuit in the third example of the second embodiment.

In the circuit simulation in FIG. 7 and FIG. 8, the reflection coefficient of the load 150 is 0.25 (return loss (R.L.)=−12.0 dB and voltage standing wave ratio (VSWR)=1.67), and the impedance control is performed in such a manner that the reflection phase is changed from 0 degrees to 360 degrees.

FIG. 7 is a Smith chart of the circuit simulation results. In FIG. 7, the waveform 200 represents the impedance Z_{L} of the load 150, and a waveform 221 represents the impedance Z_{L}′ seen from the amplifier 2 to the load 150.

FIG. 8 is a graph with the horizontal axis representing load phase and the vertical axis representing return loss. In FIG. 8, the waveform 210 represents the return loss of the load 150, and the waveform 211 represents the return loss of the inverter circuit 3 seen from the amplifier 2.

The waveform 221 is inward of the waveform 200 on the whole. The waveform 221 is downward of the waveform 210 on the whole. That is, it is understood that the return loss is decreased. It is thus understood that the impedance Z_{L}′ approaches the value assumed in designing.

However, near a point 223 and a point 224 where the load phases are respectively 90 degrees and 270 degrees, impedance mismatching in the real part is not decreased, but impedance mismatching in the imaginary part is increased. As the result, the return loss of the inverter circuit 3 is higher than the return loss of the load 150. However, impedance mismatching in a real axis direction (real part) is sufficiently low, and thus it is understood that it is sufficiently practical.

### Third Embodiment

Among components in a third embodiment, the same components as those in any one of the other embodiments are denoted by the same reference numerals, and description thereof is omitted.

In the first and second embodiments, the inverter circuit 3 is the ¼ wavelength line. However, it suffices that in the inverter circuit 3, the diagonal elements of a dependent parameter (see the right side of Formula (3)) is 0 at the operating frequency, and various variations are considered. The diagonal elements is ideally 0 in discussion, and the absolute value of the product of the diagonal elements is only required to be smaller than the absolute value of the product of off-diagonal elements at the used frequency. Circuits having the characteristics as described above will be exemplified and enumerated.

### First Example

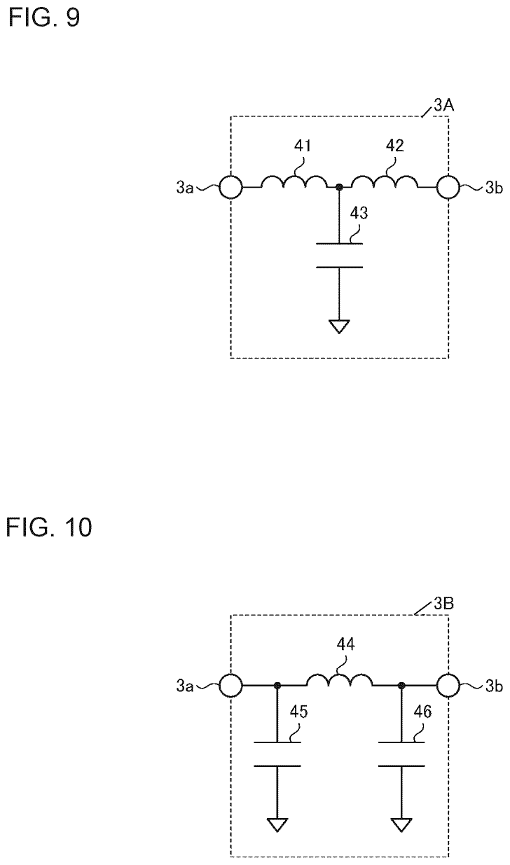

FIG. 9 is a diagram illustrating the configuration of an inverter circuit in a first example of the third embodiment.

An inverter circuit 3A includes inductors 41 and 42 and a capacitor 43.

An end of the inductor 41 is electrically connected to the end 3a of the inverter circuit 3A. A different end of the inductor 41 is electrically connected to an end of the inductor 42 and an end of the capacitor 43.

A different end of the capacitor 43 is electrically connected to the reference potential.

A different end of the inductor 42 is electrically connected to the different end 3b of the inverter circuit 3A.

The inverter circuit 3A may be considered as a T-type low pass filter.

### Second Example

FIG. 10 is a diagram illustrating the configuration of an inverter circuit in a second example of the third embodiment.

An inverter circuit 3B includes an inductor 44 and capacitors 45 and 46.

An end of the inductor 44 is electrically connected to the end 3a of the inverter circuit 3B and an end of the capacitor 45. A different end of the inductor 44 is electrically connected to the different end 3b of the inverter circuit 3B and an end of the capacitor 46.

A different end of the capacitor 45 and a different end of the capacitor 46 are electrically connected to the reference potential.

The inverter circuit 3B may be considered as a π-type low pass filter.

### Third Example

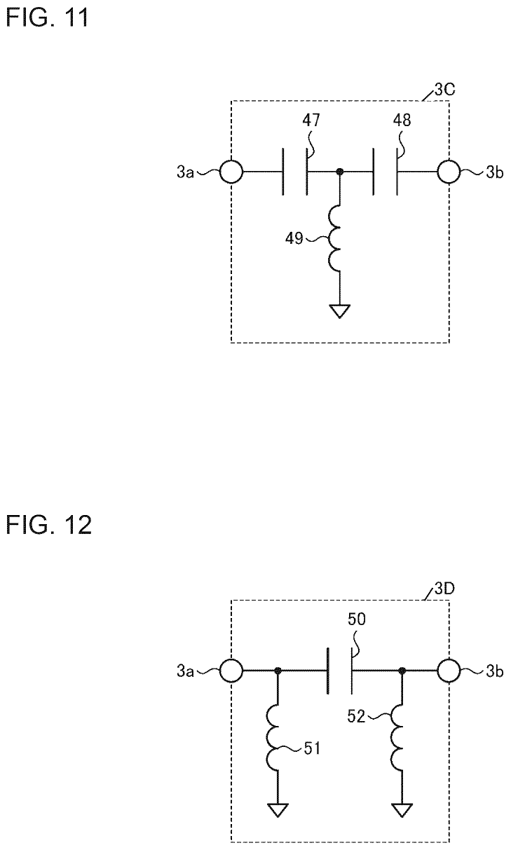

FIG. 11 is a diagram illustrating the configuration of an inverter circuit in a third example of the third embodiment.

An inverter circuit 3C includes capacitors 47 and 48 and an inductor 49.

An end of the capacitor 47 is electrically connected to the end 3a of the inverter circuit 3C. A different end of the capacitor 47 is electrically connected to an end of the capacitor 48 and an end of the inductor 49.

A different end of the inductor 49 is electrically connected to the reference potential.

A different end 3b of the capacitor 48 is electrically connected to the different end of the inverter circuit 3C.

The inverter circuit 3C may be considered as a T-type high pass filter.

### Fourth Example

FIG. 12 is a diagram illustrating the configuration of an inverter circuit in a fourth example of the third embodiment.

An inverter circuit 3D includes a capacitor 50 and inductors 51 and 52.

An end of the capacitor 50 is electrically connected to the end 3a of the inverter circuit 3D and an end of the inductor 51. A different end of the capacitor 50 is electrically connected to the different end 3b of the inverter circuit 3D and an end of the inductor 52.

A different end of the inductor 51 and a different end of the inductor 52 are electrically connected to the reference potential.

The inverter circuit 3D may be considered as a π-type high pass filter.

### Fifth Example

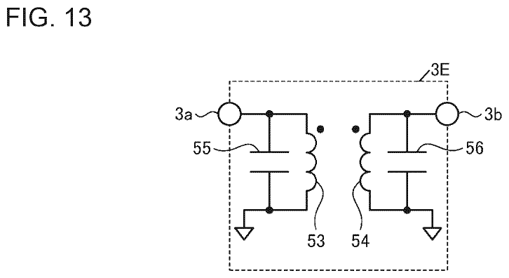

FIG. 13 is a diagram illustrating the configuration of an inverter circuit in a fifth example of the third embodiment.

An inverter circuit 3E includes a first winding 53, a second winding 54, and capacitors 55 and 56.

The first winding 53 and the second winding 54 are electromagnetically coupled.

The capacitor 55 is electrically connected in parallel to the first winding 53.

The capacitor 56 is electrically connected in parallel to the second winding 54.

An end of the first winding 53 and an end of the capacitor 55 are electrically connected to the end 3a of the inverter circuit 3E. A different end of the first winding 53 and a different end of the capacitor 55 are electrically connected to the reference potential.

An end of the second winding 54 and an end of the capacitor 56 are electrically connected to the different end 3b of the inverter circuit 3E. A different end of the second winding 54 and a different end of the capacitor 56 are electrically connected to the reference potential.

The inverter circuit 3E may be considered as a transducer.

As described above, the inverter circuit 3 may be replaced with one of various circuits, and band widening and downsizing are expectable.

### Fourth Embodiment

Among components in a fourth embodiment, the same components as those in any one of the other embodiments are denoted by the same reference numerals, and description thereof is omitted.

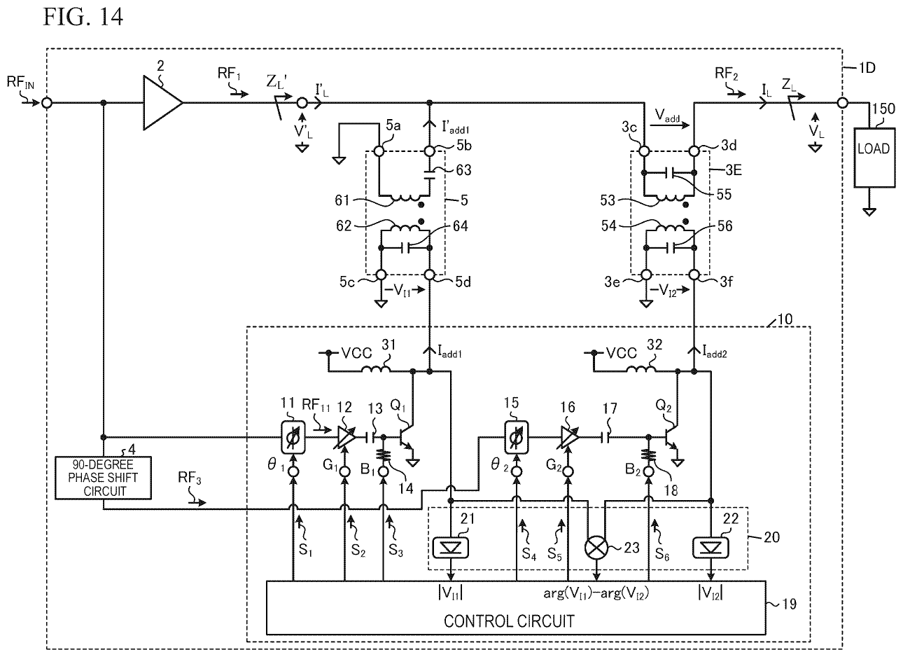

AS long as an inverter circuit is configured to be used as a balun such as the inverter circuit 3E (see FIG. 13), the impedance control may be implemented even if the current I_{L}′ (or a voltage Vadd converted from the current I_{L}′) is injected in series, as illustrated in subsequent FIG. 14.

FIG. 14 is a diagram illustrating the configuration of an amplifier circuit of the fourth embodiment.

An amplifier circuit 1D includes the inverter circuit 3E instead of the inverter circuit 3, as compared with the amplifier circuit 1 (see FIG. 1). The amplifier circuit 1D further includes a scaler circuit 5, as compared with the amplifier circuit 1.

The end of the first winding 53 and the end of the capacitor 55 of the inverter circuit 3E are electrically connected to a first terminal 3c of the inverter circuit 3E. The different end of the first winding 53 and the different end of the capacitor 55 are electrically connected to a second terminal 3d of the inverter circuit 3E.

The end of the second winding 54 of the inverter circuit 3E and the end of the capacitor 56 are electrically connected to a third terminal 3e of the inverter circuit 3E. The different end of the second winding 54 and the different end of the capacitor 56 are electrically connected to a fourth terminal 3f of the inverter circuit 3E.

The first terminal 3c of the inverter circuit 3E is electrically connected to the output terminal of the amplifier 2, and the radio frequency signal RF₁ is input thereto. The second terminal 3d of the inverter circuit 3E is electrically connected to the load 150, and the radio frequency signal RF₂ is output therefrom.

The third terminal 3e of the inverter circuit 3E is electrically connected to the reference potential. The fourth terminal 3f of the inverter circuit 3E is electrically connected to the collector of the transistor Q₂, and the current I_{add2} is input thereto.

A voltage between the third terminal 3e and the fourth terminal 3f of the inverter circuit 3E is the voltage V_{I2}.

The scaler circuit 5 includes a first winding 61, a second winding 62, and capacitors 63 and 64.

An end of the first winding 61 is electrically connected to a first terminal 5a of the scaler circuit 5. A different end of the first winding 61 is electrically connected to an end of the capacitor 63 serving as a DC blocking capacitor.

A different end of the capacitor 63 is electrically connected to a second terminal 5b of the scaler circuit 5.

The end of the second winding 62 and the end of the capacitor 64 are electrically connected to a third terminal 5c of the scaler circuit 5. A different end of the second winding 62 and a different end of the capacitor 64 are electrically connected to a fourth terminal 5d of the scaler circuit 5.

The first terminal 5a and the third terminal 5c of the scaler circuit 5 are electrically connected to the reference potential.

The fourth terminal 5d of the scaler circuit 5 is electrically connected to the collector of the transistor Q₁, and the current I_{add1} is input thereto. The second terminal 5b of the scaler circuit 5 is electrically connected to the output terminal of the amplifier 2 and the first terminal 3c of the inverter circuit 3E, and current I_{add1}′ is output therefrom.

A voltage between the third terminal 5c and the fourth terminal 5d of the scaler circuit 5 is the voltage V_{I1}.

On the contrary to the inverter circuit 3E, the scaler circuit 5 is a circuit having a larger absolute value of the product of the diagonal elements of the dependent parameter than the absolute value of the product of the off-diagonal elements.

The scaler circuit 5 may be included in the impedance detection circuit 20.

If the current I_{add1} is not high, the scaler circuit 5 may output the current I_{add1}′ obtained by multiplying the current I_{add1} by the constant (for example, once or twice) to the first terminal 3c of the inverter circuit 3E.

If the current I_{add1} is sufficiently high, the scaler circuit 5 is not required. It suffices that the collector of the transistor Q₁ is electrically connected to the output terminal of the amplifier 2 and the first terminal 3c of the inverter circuit 3E to cause the current I_{add1} to be directly output from the collector of the transistor Q₁ to the first terminal 3c of the inverter circuit 3E.

If the voltage V_{L}′ is high, the scaler circuit 5 may decrease the voltage V_{L}′ to one over constant (for example, one second) and output the voltage V_{L}′ to the collector of the transistor Q₁ and the detector 21. The scaler circuit 5 may thereby prevent the transistor Q₁ from being damaged and change the detectable range of the detector 21.

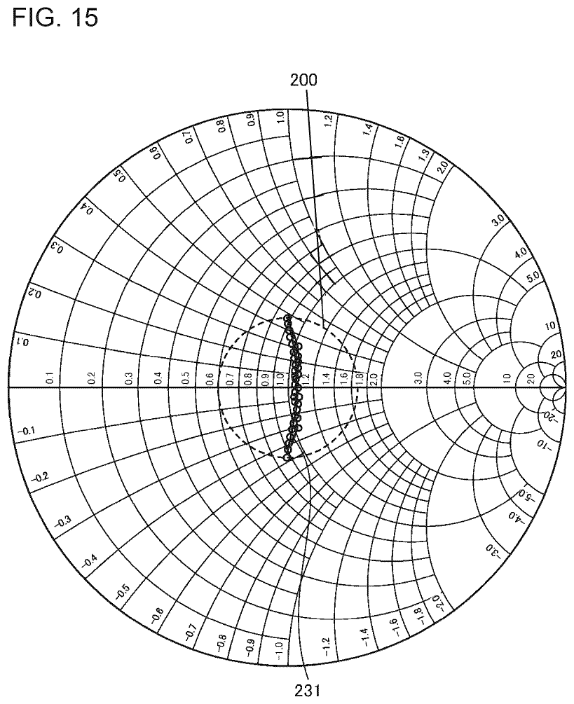

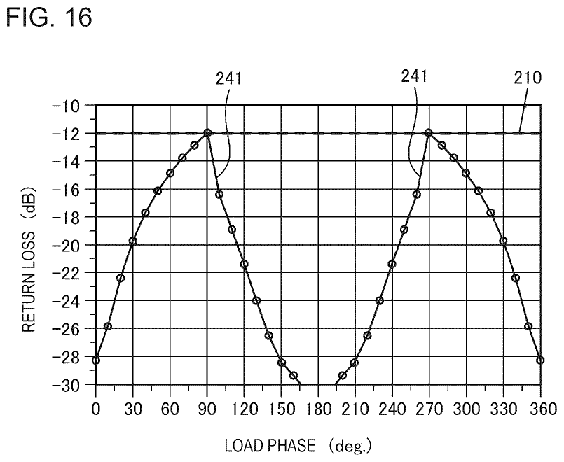

FIG. 15 and FIG. 16 are charts illustrating the circuit simulation results of the amplifier circuit of the fourth embodiment.

In the circuit simulation in FIG. 15 and FIG. 16, the reflection coefficient of the load 150 is 0.25 (return loss (R.L.)=−12.0 dB and voltage standing wave ratio (VSWR)=1.67), and the impedance control is performed in such a manner that the reflection phase is changed from 0 degrees to 360 degrees.

FIG. 15 is a Smith chart of the circuit simulation results. In FIG. 15, the waveform 200 represents the impedance Z_{L} of the load 150, and a waveform 231 represents the impedance Z_{L}′ seen from the amplifier 2 to the load 150.

FIG. 16 is a graph with the horizontal axis representing load phase and the vertical axis representing return loss. In FIG. 16, the waveform 210 represents the return loss of the load 150, and a waveform 241 represents the return loss of the inverter circuit 3E seen from the amplifier 2.

With the configuration of the amplifier circuit 1D, it is possible to freely select whether to inject the current I_{add1} and to detect the voltage V_{I1} on the load 150 side or the amplifier 2 side with respect to the inverter circuit 3E.

### Fifth Embodiment

Among components in a fifth embodiment, the same components as those in any one of the other embodiments are denoted by the same reference numerals, and description thereof is omitted.

For the first, second, and fourth embodiments, the case where one of the inverter circuit 3 to the inverter circuit 3E is additionally provided closer to the load 150 than to the amplifier 2 has heretofore been described. However, if the amplifier 2 is a Doherty amplifier, one of the inverter circuit 3 to the inverter circuit 3E is included in the Doherty combiner, and the Doherty combiner may also be used for the impedance control.

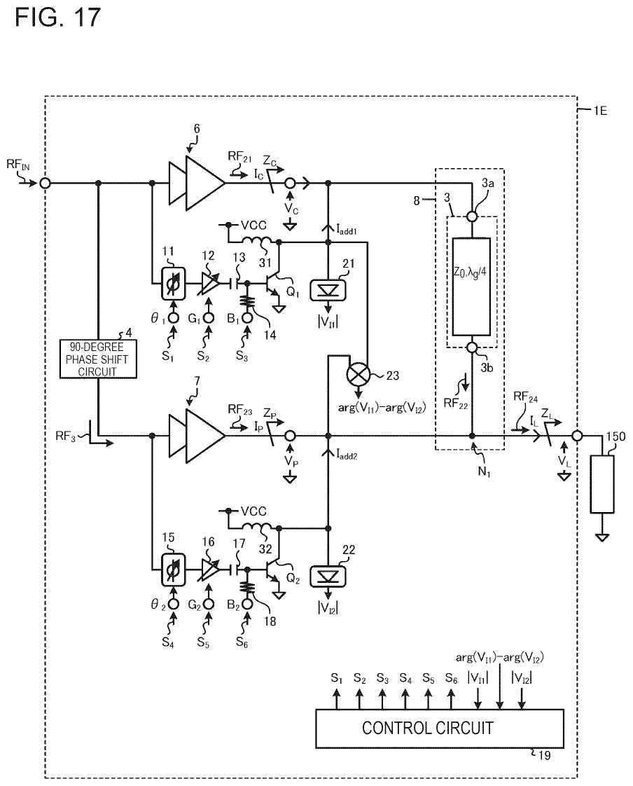

FIG. 17 is a diagram illustrating the configuration of the amplifier circuit of the fifth embodiment. An amplifier circuit 1E is a Doherty amplifier circuit.

The amplifier circuit 1E includes a carrier amplifier 6, a peaking amplifier 7, and a Doherty combiner 8 instead of the amplifier 2, as compared with the amplifier circuit 1 (see FIG. 1).

The Doherty combiner 8 includes the inverter circuit 3.

Each of the carrier amplifier 6 and the peaking amplifier 7 has two stages; however, the present disclosure is not limited to this. Each of the carrier amplifier 6 and the peaking amplifier 7 may have one stage and may have three or more stages.

The carrier amplifier 6 amplifies the radio frequency signal RF_{IN} and outputs a radio frequency signal RF₂₁ to the end 3a of the inverter circuit 3.

Impedance seen from the carrier amplifier 6 to the load 150 is impedance Z_{C}. An output voltage of the carrier amplifier 6 is a voltage V_{C}, and output current is current I_{C}.

A connection relationship among the carrier amplifier 6, the variable phase control circuit 11, the variable gain control circuit 12, the capacitor 13, the resistor 14, and the transistor Q₁ is the same as the connection relationship (see FIG. 1) among the amplifier 2, the variable phase control circuit 11, the variable gain control circuit 12, the capacitor 13, the resistor 14, and the transistor Q₁, and thus description thereof is omitted.

The inverter circuit 3 receives the radio frequency signal RF₂₁ at the end 3a and outputs a radio frequency signal RF₂₂ from the different end 3b to a node N₁.

The peaking amplifier 7 amplifies the radio frequency signal RF₃ and outputs a radio frequency signal RF₂₃ to the node N₁.

Impedance seen from the peaking amplifier 7 to the load 150 is impedance Z_{P}. An output voltage of the peaking amplifier 7 is a voltage V_{P}, and output current thereof is current I_{P}.

A connection relationship among the peaking amplifier 7, the variable phase control circuit 15, the variable gain control circuit 16, the capacitor 17, the resistor 18, and the transistor Q₂ is the same as the connection relationship (see FIG. 1) among the amplifier 2, the variable phase control circuit 11, the variable gain control circuit 12, the capacitor 13, the resistor 14, and the transistor Q₁, and thus description thereof is omitted.

At the node N₁, the radio frequency signal RF₂₂ and the radio frequency signal RF₂₃ are combined, and a radio frequency signal RF₂₄ is generated. The combined radio frequency signal RF₂₄ is output to the load 150.

The inverter circuit 3 is used for combining the radio frequency signal RF₂₂ and the radio frequency signal RF₂₃ and also for controlling impedance, and thereby downsizing may be achieved.

However, in achieving high efficiency, the Doherty amplifier circuit is characterized by variation of the impedance Z_{C} seen from the carrier amplifier 6 to the load 150 due to input power (power of the radio frequency signal RF_{IN}). Accordingly, if the technology in the first, second, and fourth embodiments is simply used for the amplifier circuit 1E, control is performed to have a constant impedance Z_{C}, and thus the efficiency is likely to be deteriorated.

Hence, the control circuit 19 may change the control of the gains G₁ and G₂ and the control of the bias voltages B₁ and B₂ according to input power (power of the radio frequency signal RF_{IN} or the radio frequency signal RF₃) or output power (power of the radio frequency signals RF₂₁, RF₂₂, or RF₂₄).

Specifically, control as in Formula (8) and Formula (9) below is conceivable as the control of the gains G₁ and G₂

$$\begin{matrix}[ Math 4 ] & \\ {G}_{1} ( dB ) = \{ \begin{matrix}{α}_{1} 10 log ( \vert {V}_{I 2} \vert - \vert {V}_{I 1} \vert - {V}_{offset} ) & ( where \vert {V}_{I 2} \vert > \vert {V}_{I 1} \vert + {V}_{offset} ) \\ - ∞ & ( where \vert {V}_{I 2} \vert \leq \vert {V}_{I 1} \vert + {V}_{offset} )\end{matrix} & ( 8 )\end{matrix}$$

$$\begin{matrix}[ Math 5 ] & \\ {G}_{2} ( dB ) = \{ \begin{matrix}{α}_{2} 10 log ( \vert {V}_{I 1} \vert - \vert {V}_{I 2} \vert - {V}_{offset} ) & ( where \vert {V}_{I 1} \vert > \vert {V}_{I 2} \vert + {V}_{offset} ) \\ - ∞ & ( where \vert {V}_{I 1} \vert \leq \vert {V}_{I 2} \vert + {V}_{offset} )\end{matrix} & ( 9 )\end{matrix}$$

In Formula (8) and (9), Voffset is a parameter varying with the input power or the output power.

The amplifier circuit 1E may thereby match the impedance Z_{C} seen from the carrier amplifier 6 to the load 150 with different impedance according to the input power or the output power.

### Sixth Embodiment

Among components in a sixth embodiment, the same components as those in any one of the other embodiments are denoted by the same reference numerals, and description thereof is omitted.

For the fifth embodiment, the case where each of the carrier amplifier 6 and the peaking amplifier 7 has a single-ended output configuration and where the Doherty combiner 8 combines the radio frequency signal RF₂₁ and the radio frequency signal RF₂₃ in parallel has heretofore been described. However, the present disclosure is not limited to this. Each of the carrier amplifier and the peaking amplifier may have a differential output configuration, and the Doherty combiner may combine two differential signals in series.

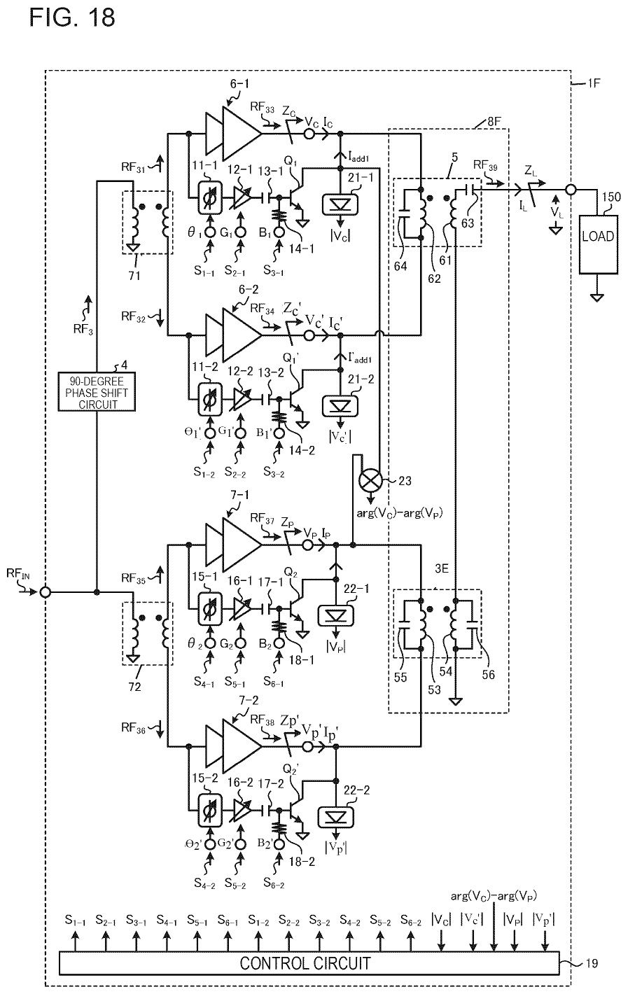

FIG. 18 is a diagram illustrating the configuration of an amplifier circuit of the sixth embodiment. An amplifier circuit 1F is a Doherty amplifier circuit.

The amplifier circuit 1F includes carrier amplifiers 6-1 and 6-2 instead of the carrier amplifier 6, as compared with the amplifier circuit 1E (see FIG. 17). The amplifier circuit 1F includes peaking amplifiers 7-1 and 7-2 instead of the peaking amplifier 7, as compared with the amplifier circuit 1E. The amplifier circuit 1F includes a Doherty combiner 8F instead of the Doherty combiner 8, as compared with the amplifier circuit 1E. The Doherty combiner 8F includes the inverter circuit 3E and the scaler circuit 5. The amplifier circuit 1F further includes baluns 71 and 72, as compared with the amplifier circuit 1E.

The carrier amplifier 6-1 and the carrier amplifier 6-2 form a differential carrier amplifier. The carrier amplifier 6-1 is a positive polarity carrier amplifier. The carrier amplifier 6-2 is a negative polarity carrier amplifier.

The peaking amplifier 7-1 and the peaking amplifier 7-2 form a differential peaking amplifier 7-2. The peaking amplifier 7-1 is a positive polarity peaking amplifier. The peaking amplifier 7-2 is a negative polarity peaking amplifier.

Each of the carrier amplifiers 6-1 and 6-2 as well as the peaking amplifiers 7-1 and 7-2 has two stages; however, the present disclosure is not limited to this. Each of the carrier amplifiers 6-1 and 6-2 as well as the peaking amplifiers 7-1 and 7-2 may have one stage and may have three or more stages.

The balun 71 outputs radio frequency signals RF₃₁ and RF₃₂ constituting a differential signal, based on the radio frequency signal RF₃.

The carrier amplifier 6-1 amplifies the radio frequency signal RF₃₁ and outputs a radio frequency signal RF₃₃ to the end of the second winding 62 of the scaler circuit 5.

Impedance seen from the carrier amplifier 6-1 to the load 150 is the impedance Z_{C}. An output voltage of the carrier amplifier 6-1 is the voltage V_{C}, and output current thereof is the current I_{C}.

A connection relationship among the carrier amplifier 6-1, a variable phase control circuit 11-1, a variable gain control circuit 12-1, a capacitor 13-1, a resistor 14-1, and the transistor Q₁ is the same as the connection relationship (see FIG. 1) among the amplifier 2, the variable phase control circuit 11, the variable gain control circuit 12, the capacitor 13, the resistor 14, and the transistor Q₁, and thus description thereof is omitted.

The carrier amplifier 6-2 amplifies a radio frequency signal RF₃₂ and outputs a radio frequency signal RF₃₄ to the different end of the second winding 62 of the scaler circuit 5.

Impedance seen from the carrier amplifier 6-2 to the load 150 is impedance Z_{C}′. An output voltage of the carrier amplifier 6-2 is a voltage V_{C}′, and output current thereof is current I_{C}′.

A connection relationship among the carrier amplifier 6-2, a variable phase control circuit 11-2, a variable gain control circuit 12-2, a capacitor 13-2, a resistor 14-2, and a transistor Q₁′ is the same as the connection relationship (see FIG. 1) among the amplifier 2, the variable phase control circuit 11, the variable gain control circuit 12, the capacitor 13, the resistor 14, and the transistor Q₁, and thus description thereof is omitted.

The balun 72 outputs radio frequency signals RF₃₅ and RF₃₆ constituting a differential signal, based on the radio frequency signal RF_{IN}.

The peaking amplifier 7-1 amplifies the radio frequency signal RF₃₅ and outputs a radio frequency signal RF₃₇ to the end of the first winding 53 of the inverter circuit 3E.

Impedance seen from the peaking amplifier 7-1 to the load 150 is the impedance Z_{P}. An output voltage of the peaking amplifier 7-1 is the voltage V_{P}, and output current thereof is the current I_{P}.

A connection relationship among the peaking amplifier 7-1, a variable phase control circuit 15-1, a variable gain control circuit 16-1, a capacitor 17-1, a resistor 18-1, and the transistor Q₂ is the same as the connection relationship (see FIG. 1) among the amplifier 2, the variable phase control circuit 11, the variable gain control circuit 12, the capacitor 13, the resistor 14, and the transistor Q₁, and thus description thereof is omitted.

The peaking amplifier 7-2 amplifies the radio frequency signal RF₃₆ and outputs a radio frequency signal RF₃₈ to the different end of the first winding 53 of the inverter circuit 3E.

Impedance seen from the peaking amplifier 7-2 to the load 150 is impedance Z_{P}′. An output voltage of the peaking amplifier 7-2 is a voltage V_{P}′, and output current thereof is current I_{P}′.

A connection relationship among the peaking amplifier 7-2, a variable phase control circuit 15-2, a variable gain control circuit 16-2, a capacitor 17-2, a resistor 18-2, and a transistor Q₂′ is the same as the connection relationship (see FIG. 1) among the amplifier 2, the variable phase control circuit 11, the variable gain control circuit 12, the capacitor 13, the resistor 14, and the transistor Q₁, and thus description thereof is omitted.

The end of the second winding 54 of the inverter circuit 3E is electrically connected to the reference potential. The different end of the second winding 54 of the inverter circuit 3E is electrically connected to the end of the first winding 61 of the scaler circuit 5. A radio frequency signal RF₃₉ obtained by combining the differential signal (radio frequency signals RF₃₃ and RF₃₄) and the differential signal (radio frequency signals RF₃₇ and RF₃₈) in series is output from the capacitor 63 of the scaler circuit 5 to the load 150.

In this embodiment, the phase difference detector 23 detects a phase difference (arg(V_{C})−arg(V_{P})) between the radio frequency signal RF₃₃ that is an output signal of the positive polarity carrier amplifier 6-1 and the radio frequency signal RF₃₇ that is an output signal of the positive polarity peaking amplifier 7-1; however, the present disclosure is not limited to this. The phase difference detector 23 may detect a phase difference between the radio frequency signal RF₃₄ that is an output signal of the negative polarity carrier amplifier 6-2 and the radio frequency signal RF₃₈ that is an output signal of the negative polarity peaking amplifier 7-2. The phase difference detector 23 may also detect a phase difference between the radio frequency signal RF₃₃ that is the output signal of the positive polarity carrier amplifier 6-1 and the radio frequency signal RF₃₈ that is the output signal of the negative polarity peaking amplifier 7-2. The phase difference detector 23 may also detect a phase difference between the radio frequency signal RF₃₄ that is the output signal of the negative polarity carrier amplifier 6-2 and the radio frequency signal RF₃₇ that is the output signal of the positive polarity peaking amplifier 7-1. The phase difference detector 23 may also average two or more of the phases described above.

Further, the phase difference detector 23 may calculate a phase difference between the carrier side and the peak side by using the amplitude, the phase, or the like of the differential signal (radio frequency signals RF₃₃ and RF₃₄) on the carrier side and the differential signal (radio frequency signals RF₃₇ and RF₃₈) on the peak side.

A phase control signal S₁₋₂ input to the variable phase control circuit 11-2 on the negative polarity side, a gain control signal S₂₋₂ input to the variable gain control circuit 12-2, and a bias control signal S₃₋₂ input to the resistor 14-2 may be respectively same as a phase control signal S₁₋₁ input to the variable phase control circuit 11-1 on the positive polarity side, a gain control signal S₂₋₁ input to the variable gain control circuit 12-1, and a bias control signal S₃₋₁ input to the resistor 14-1; however, the present disclosure is not limited to this.

A gain, a phase difference, and a bias point may be controlled by using a result of comparison between the radio frequency signal RF₃₃ and the radio frequency signal RF₃₄ (for example, comparison between |V_{C}| and |V_{C}′| such as arg(V_{C})−arg(V_{C}′)). The amplifier circuit 1F may thereby reduce an influence on the differential pair caused by the load variation.

A phase control signal S₄₋₂ input to the variable phase control circuit 15-2, a gain control signal S₅₋₂ input to the variable gain control circuit 16-2, and a bias control signal S₆₋₂ input to the resistor 18-2 are the same as described above.

### Seventh Embodiment

Among components in a seventh embodiment, the same components as those in any one of the other embodiments are denoted by the same reference numerals, and description thereof is omitted.

The load detection technology in the first to sixth embodiments may be combined with another control technology. For example, a case where a target amplifier is a Doherty amplifier will be described. There is typically a possibility that the characteristics of the Doherty amplifier largely vary (performance deterioration) in response to the load variation, as described above. The amplifier circuit 1F of the sixth embodiment described above may improve the characteristic variation described above but may improve the characteristic variation described above also in the seventh embodiment.

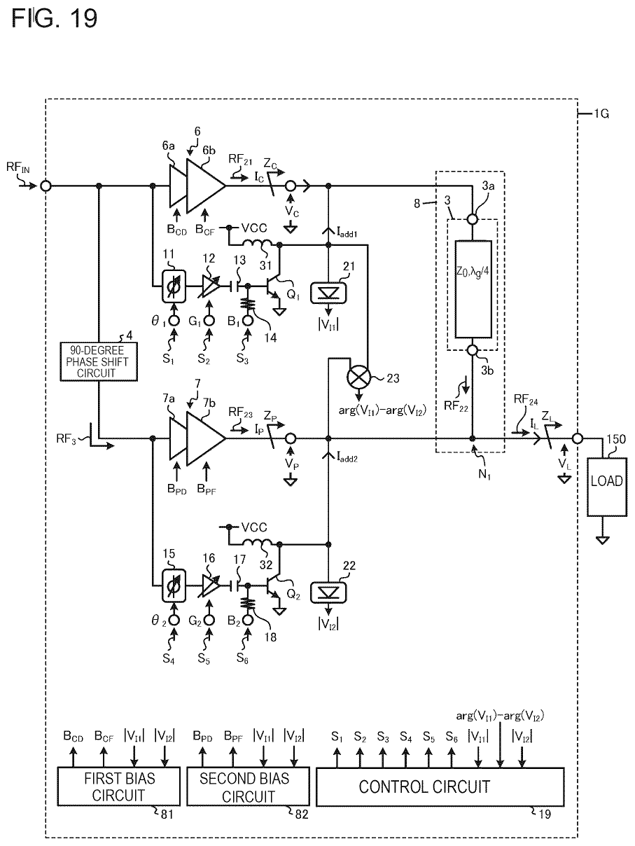

FIG. 19 is a diagram illustrating the configuration of an amplifier circuit of the seventh embodiment. An amplifier circuit 1G is a Doherty amplifier circuit.

The amplifier circuit 1G includes a first bias circuit 81, as compared with the amplifier circuit 1E (see FIG. 17). The first bias circuit 81 performs variable control of a bias of the carrier amplifier 6. The amplifier circuit 1G includes a second bias circuit 82, as compared with the amplifier circuit 1E. The second bias circuit 82 performs variable control of a bias of the peaking amplifier 7.

Based on the voltage amplitude |V_{I1}| and the voltage amplitude |V_{I2}|, the first bias circuit 81 outputs a bias signal B_{CD} to the base (or the gate) of a first stage amplifier 6a of the carrier amplifier 6 and outputs a bias signal B_{CF} to the base (or the gate) of a final stage amplifier 6b.

Based on the voltage amplitude |V_{I1}| and the voltage amplitude |V_{I2}|, the second bias circuit 82 outputs a bias signal B_{PD} to the base (or the gate) of a first stage amplifier 7a of the peaking amplifier 7 and outputs a bias signal B_{PF} to the base (or the gate) of a final stage amplifier 7b.

Typically, it is known that the characteristic variation in response to the load variation in the Doherty amplifier may be improved by controlling a bias of the base (or the gate) of one or more of amplifiers in respective stages of the carrier amplifier and amplifiers in respective stages of the peaking amplifier. The amplifier circuit 1G controls, in accordance with the load condition, a bias of one or more of the first stage amplifier 6a and the final stage amplifier 6b of the carrier amplifier 6 and the first stage amplifier 7a and the final stage amplifier 7b of the peaking amplifier 7 and thereby may provide a high performance Doherty amplifier even if the load variation occurs.

Hereinafter, control of the amplifier circuit 1G, for example, in a case of low impedance will be described. In a case of high impedance, similar effects are provided by performing control for reverse operations.

Low impedance of the load 150 leads to, for example, |V_{I2}|>|V_{I1}|. In this case, the impedance Z_{C} seen from the carrier amplifier 6 to the load 150 becomes high. If the impedance Z_{C} becomes high, the gain of the carrier amplifier 6 changes to be higher, and saturation power changes to be lower. The amplifier circuit 1G performs control to compensate for this and thereby may prevent the characteristic variation due to the load variation.

Specifically, the first bias circuit 81 decreases the impedance of the bias signals B_{CD} and B_{CF} to have impedance lower than in the case of the assumed impedance (for example, in the case of |V_{I2}|=|V_{I1}|) and prevents the gain of the carrier amplifier 6 from increasing. In addition, the second bias circuit 82 increases the bias signals B_{PD} and B_{PE} to have impedance higher than in the case of the assumed impedance. This causes the peaking amplifier 7 to start, and thus early saturation in the carrier amplifier 6 due to low saturation power of the carrier amplifier 6 may be compensated.

For the seventh embodiment, the case where the amplifier circuit 1G combines the radio frequency signal RF₂₁ and the radio frequency signal RF₂₃ in parallel has heretofore been described; however, the present disclosure is not limited to this. If the amplifier circuit 1G combines the radio frequency signal RF₂₁ and the radio frequency signal RF₂₃ in series, the polarity of a detected voltage and the polarity for bias control are opposite polarities from those in the case of the parallel combination described above.

For a bias point of the peaking amplifier 7, control technology in, for example, U.S. Patent Application Publication No. 2021/0036661 Specification and U.S. Patent Application Publication No. 2016/0241209 Specification may be used. A voltage amplitude comparison result or a voltage phase comparison result is reflected on a bias point of the peaking amplifier 7, and thereby a Doherty amplifier compensated for the load variation may be provided.

### (Equivalent Circuit)

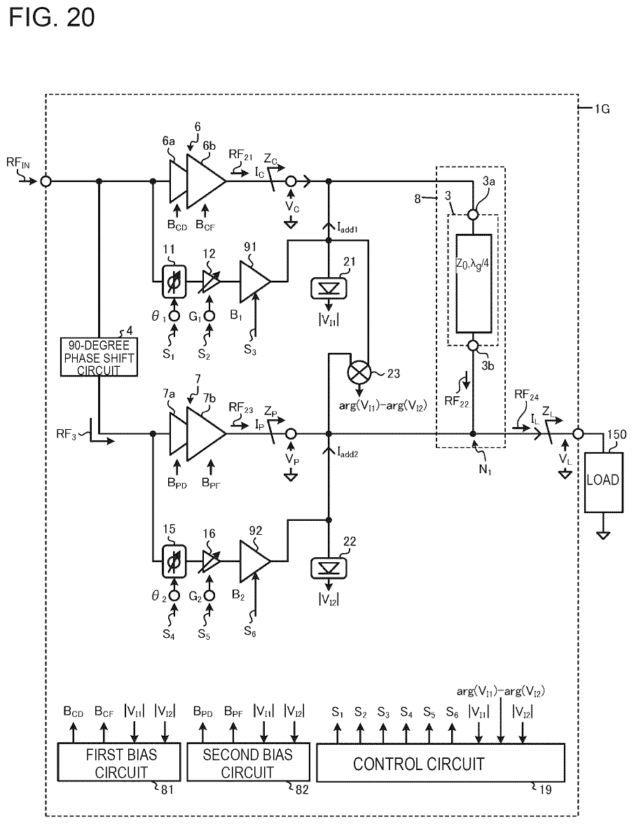

FIG. 20 is a diagram illustrating the configuration of an equivalent circuit of the amplifier circuit of the seventh embodiment.

An amplifier 91 in FIG. 20 corresponds to integration of the capacitor 13, the resistor 14, and the transistor Q₁ in FIG. 19. An amplifier 92 corresponds to integration of the capacitor 17, the resistor 18, and the transistor Q₂ in FIG. 19.

It is understood that the amplifier 91 for impedance control (transistor Q₁) is connected in parallel to the final stage amplifier 6b of the carrier amplifier 6.

It is understood that the amplifier 92 for impedance control (transistor Q₂) is connected in parallel to the final stage amplifier 7b of the peaking amplifier 7.

### Eighth Embodiment

Among components in an eighth embodiment, the same components as those in any one of the other embodiments are denoted by the same reference numerals, and description thereof is omitted.

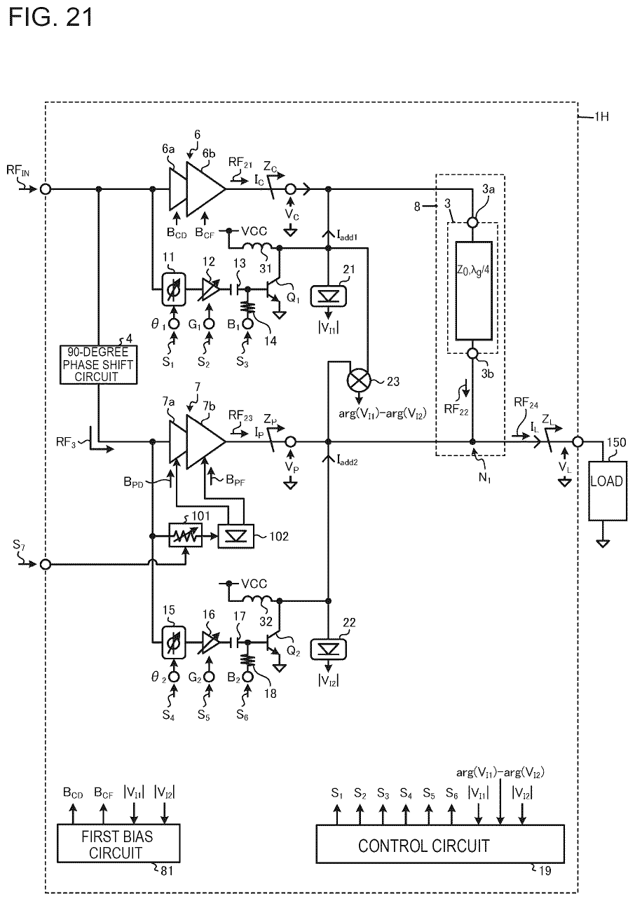

FIG. 21 is a diagram illustrating the configuration of the amplifier circuit of the eighth embodiment. An amplifier circuit 1H is a Doherty amplifier circuit.

The amplifier circuit 1H includes a variable attenuator 101 and a detector 102 instead of the second bias circuit 82, as compared with the amplifier circuit 1G (see FIG. 19).

The variable attenuator 101 attenuates the radio frequency signal RF₃ based on a signal S₇ and outputs the radio frequency signal RF₃ to the detector 102. The signal S₇ is a signal representing the drive level of the final stage amplifier 6b of the carrier amplifier 6, and a saturation signal or a load detection signal is exemplified; however, the present disclosure is not limited to this. The signal S₇ is also a signal representing the level of the input power (power of the radio frequency signal RF_{IN}). The detector 102 detects a radio frequency signal attenuated by the variable attenuator 101 and outputs the bias signals B_{PD} and B_{PF} respectively to the first stage amplifier 7a and the final stage amplifier 7b.

Even if input power (power of the radio frequency signal RF_{IN}) is not high, the amplifier circuit 1H may perform circuit operations on which the load status is reflected and thus prevent control delay.

### (Modification)

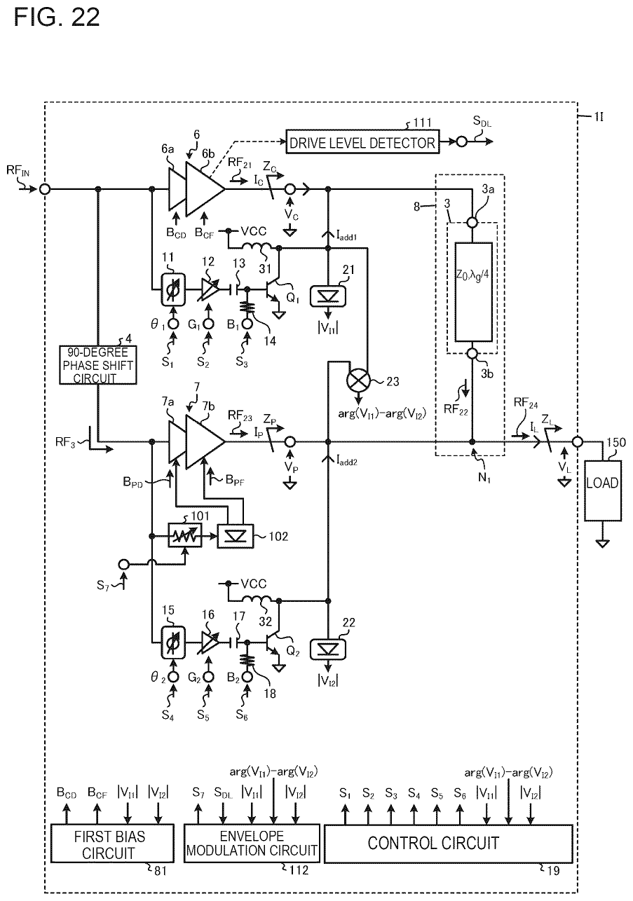

FIG. 22 is a diagram illustrating the configuration of an amplifier circuit of a modification of the eighth embodiment.

An amplifier circuit 1I further includes a drive level detector 111 and an envelope modulation circuit 112, as compared with the amplifier circuit 1H (see FIG. 21).

The drive level detector 111 detects the drive level of the final stage amplifier 6b of the carrier amplifier 6 and outputs a signal SDL representing the drive level to the envelope modulation circuit 112. In an example, the drive level detector 111 detects the drive level of the final stage amplifier 6b based on a voltage or current of an amplifying transistor in the final stage amplifier 6b or a voltage or current of the transistor in the first bias circuit 81; however, the present disclosure is not limited to this. The signal SDL is also a signal representing the level of input power (power of the radio frequency signal RF_{IN}).

The envelope modulation circuit 112 outputs the signal S₇ to the variable attenuator 101 based on the voltage amplitude |V_{I1}|, the voltage amplitude |V_{I2}|, the phase difference (arg(V_{I1})−arg(V_{I2})), and the signal SDL.

With the amplifier circuit 1I, an adaptive Doherty amplifier capable of impedance control may be achieved.

The embodiments described above have been provided for easier understanding of the present disclosure and are not intended to limit the interpretation of the present disclosure. The present disclosure may be changed/improved without necessarily departing from the spirit thereof and includes its equivalents.

### REFERENCE SIGNS LIST

1, 1A, 1B, 1C, 1D, 1E, 1F, 1G, 1H amplifier circuit
2, 91, 92 amplifier
3, 3A, 3B, 3C, 3D, 3E inverter circuit
4 90-degree shift circuit
5 scaler circuit
6, 6-1, 6-2 carrier amplifier
7, 7-1, 7-2 peaking amplifier
8, 8F Doherty combiner
10, 10A, 10B, 10C impedance control circuit
11, 11-1, 11-2, 15, 15-1, 15-2 variable phase control circuit
12, 12-1, 12-2, 16, 16-1, 16-2 variable gain control circuit
13, 13-1, 13-2, 17, 17-1, 17-2 capacitor
14, 14-1, 14-2, 18, 18-1, 18-2 resistor
19 control circuit
20, 20C impedance detection circuit
21, 22, 102 detector
23 phase difference detector
71, 72 balun
81 first bias circuit
82 second bias circuit
101 variable attenuator
111 drive level detector
112 envelope modulation circuit

1. An impedance detection circuit comprising:
a first detector configured to detect a first voltage amplitude at a first end of an inverter circuit, the inverter circuit being configured to receive a radio frequency signal at the first end and output a signal from a second end;
a second detector configured to detect a second voltage amplitude of the second end of the inverter circuit; and
a phase difference detector configured to detect a phase difference between a phase of a voltage across the first end of the inverter circuit and a phase of a voltage across the second end of the inverter circuit,
wherein an absolute value of a product of diagonal elements of a dependent parameter for the inverter circuit is smaller than an absolute value of a product of off-diagonal elements.

2. The impedance detection circuit according to claim 1, further comprising:
a scaler circuit having a first end electrically connected to the first end of the inverter circuit and a second end electrically connected the first detector,
wherein an absolute value of a product of diagonal elements of a dependent parameter for the scaler circuit is larger than an absolute value of a product of off-diagonal elements of the dependent parameter.

3. An impedance control circuit comprising:
the impedance detection circuit according to claim 1; and
a first transistor or a second transistor, the first transistor having a base or a gate to which a first signal based on the first voltage amplitude and the second voltage amplitude is input and having a collector or a drain configured to output a first current to the first end of the inverter circuit, the second transistor having a base or a gate to which a second signal based on the first voltage amplitude and the second voltage amplitude is input and having a collector or a drain configured to output a second current to the second end of the inverter circuit.

4. The impedance control circuit according to claim 3,
wherein the first transistor is configured to output the first current to the first end of the inverter circuit in response to a low input impedance of the inverter circuit.

5. The impedance control circuit according to claim 4, further comprising:
a first variable gain control circuit configured to change an amplitude of the radio frequency signal based on the first voltage amplitude and the second voltage amplitude,
wherein the first variable gain control circuit is configured to supply the radio frequency signal to the base or the gate of the first transistor.

6. The impedance control circuit according to claim 5, further comprising:
a first variable phase control circuit configured to change a phase of the radio frequency signal based on the first voltage amplitude, the second voltage amplitude, and the phase difference between the phase of the voltage across the first end of the inverter circuit and the phase of the voltage across the second end of the inverter circuit.

7. The impedance control circuit according to claim 3,
wherein the second transistor is configured to output the second current to the second end of the inverter circuit in response to a high input impedance of the inverter circuit.

8. The impedance control circuit according to claim 7, further comprising:
a second variable gain control circuit configured to change an amplitude of the radio frequency signal based on the first voltage amplitude and the second voltage amplitude,
wherein the second variable gain control circuit is configured to output the radio frequency signal to the base or the gate of the second transistor.

9. The impedance control circuit according to claim 8, further comprising:
a second variable phase control circuit configured to change a phase of the radio frequency signal based on the first voltage amplitude, the second voltage amplitude, and the phase difference between the phase of the voltage across the first end of the inverter circuit and the phase of the voltage across the second end of the inverter circuit.

10. A Doherty amplifier circuit comprising:
a carrier amplifier configured to amplify an input radio frequency signal;
a peaking amplifier configured to amplify the input radio frequency signal; and
the impedance control circuit according to claim 3,
wherein the inverter circuit is a Doherty combiner configured to combine a signal output by the carrier amplifier and a signal output by the peaking amplifier.

11. The Doherty amplifier circuit according to claim 10,
wherein the carrier amplifier or the peaking amplifier is biased based on the first voltage amplitude and the second voltage amplitude.

12. The Doherty amplifier circuit according to claim 10,
wherein the peaking amplifier is biased based on a power of the input radio frequency signal.

13. The Doherty amplifier circuit according to claim 11,
wherein the peaking amplifier is biased based on a power of the input radio frequency signal.

14. An impedance control circuit comprising:
the impedance detection circuit according to claim 2; and
a first transistor or a second transistor, the first transistor having a base or a gate to which a first signal based on the first voltage amplitude and the second voltage amplitude is input and having a collector or a drain configured to output a first current to the first end of the inverter circuit, the second transistor having a base or a gate to which a second signal based on the first voltage amplitude and the second voltage amplitude is input and having a collector or a drain configured to output a second current to the second end of the inverter circuit.
